(19) United States
(12) Patent Application Publication
(10) Pub. No.: US 2015/0189053 A1
(43) Pub. Date: Jul. 2, 2015

(54) Mobile Phone Case with Heating Element

(71) Applicant: Nicholas David LaHam, Woodridge, IL (US)

(72) Inventor: Nicholas David LaHam, Woodridge, IL (US)

(21) Appl. No.: 14/142,803

(22) Filed: Dec. 28, 2013

(51) Int. Cl. H04M 1/11; H05K 5/02; H05B 1/02; H05K 5/00

(52) U.S. Cl. CPC H04M 1/11; H05K 5/0086; H05K 5/0247; H05B 1/0225; H01M 10/615

(57) ABSTRACT

A mobile phone case that is characterized by an on-board electrical heating element which is exposed through the mechanical action of a retractable cover. The heating element utilizes resistive heating by inducing electrical current through a small coil housed on the back of the phone case. The heating coil is powered by an internal battery and when activated, is used to ignite common materials normally accomplished by the use of a traditional butane lighter. The cover that shields the element is simultaneously used to activate a switch on an internal circuit to allow power to be sent to the heating coil and heat to a temperature high enough for wick-lick and paper materials to ignite. The cover and phone case material is designed with materials to prevent burning of the case and so heat is only transferred to the intended object.

### FIELD OF THE INVENTION

The present invention relates generally to the field of mobile phone cases, and more specifically, to mobile phone cases having a heating capability.

### BACKGROUND OF THE INVENTION

The mobile phone has become the mainstream of telecommunications, replacing traditional wired technology. For carrying a mobile phone, many people place the mobile phone in a mobile phone case. There is a large variety of mobile phone cases on the market today and most changes that have evolved in mobile phone cases have involved personalized and customized phone accessories.

### SUMMARY OF THE INVENTION

Embodiments are disclosed relating to a technologically advanced mobile phone case. Systems and devices for a mobile phone case, enclosing a battery and a heating element are provided.

According to embodiments disclosed herein, a mobile phone case preferably includes a battery, control circuitry, switches, a charging receptacle, an adapter, and a resistive heating element. The preferred adapter is configured to connect to a charging port on a mobile phone housed within the case. Preferably a switch on the case can be activated to allow the battery enclosed within the case to provide electrical power through the adapter to charge the mobile phone battery. In addition to this switch, two other switches may be located on the case: a spring-return slide switch and a momentary switch. The preferred slide switch, when in a closed position, covers up the resistive heating element. When the momentary switch is activated and the slide switch is moved to expose the heating element, the battery can power the heating element to provide thermal heat to ignite, for example, tobacco products, such as a cigarette or other combustible products, such as candles and wicks. Thus, the battery can provide an electrical charge to the mobile phone battery or it can provide electrical power to operate the heating element.

In an exemplary embodiment, the mobile phone case may also include a timer circuit that limits the time that the heating element will be activated despite the simultaneous use of the momentary switch and the slide switch. Preferably the timer circuit will automatically stop powering the heating element after a specified amount of time. In turn, a user continuously depressing the momentary switch and holding the slide switch open cannot compromise the safety of the heating element or power the element for a continuous period if both switches are activated by accident. This embodiment provides three backups for safely operating the device and preventing accidental operation when in a pocket or purse.

According to another exemplary embodiment, the heating element is attached to a cartridge, which is movably attached to the mobile phone case. As such, users can swap in a replacement cartridge, should the original heating element or cartridge fail.

Alternative exemplary embodiments relate to other features and combinations of features as may be generally recited in the claims and later in the specification.

### BRIEF DESCRIPTION OF THE DRAWINGS

FIG. 1 is a rear perspective view of a mobile phone case and heating element, according to an exemplary embodiment, including a cigarette being ignited by the heating element of the case.

FIG. 2 is a partially exploded front view of the mobile phone case of FIG. 1 with a heating element cartridge door in an open position according to an exemplary embodiment.

FIG. 3 is a perspective view of a heating element cartridge that holds a heating element which may be used with the mobile phone case of FIG. 1 according to an exemplary embodiment.

FIG. 4 is a partially exploded front view of the mobile phone case of FIG. 1 including an exemplary mobile phone.

FIG. 5 is a perspective view of the mobile phone case of FIG. 1 with an exemplary mobile phone.

FIG. 6 is a schematic diagram of a circuit capable for use with the mobile phone case of FIG. 1.

FIG. 7 is a schematic diagram of a future embodiment of a circuit cable for use with the mobile phone case of FIG. 1.

### DETAILED DESCRIPTION

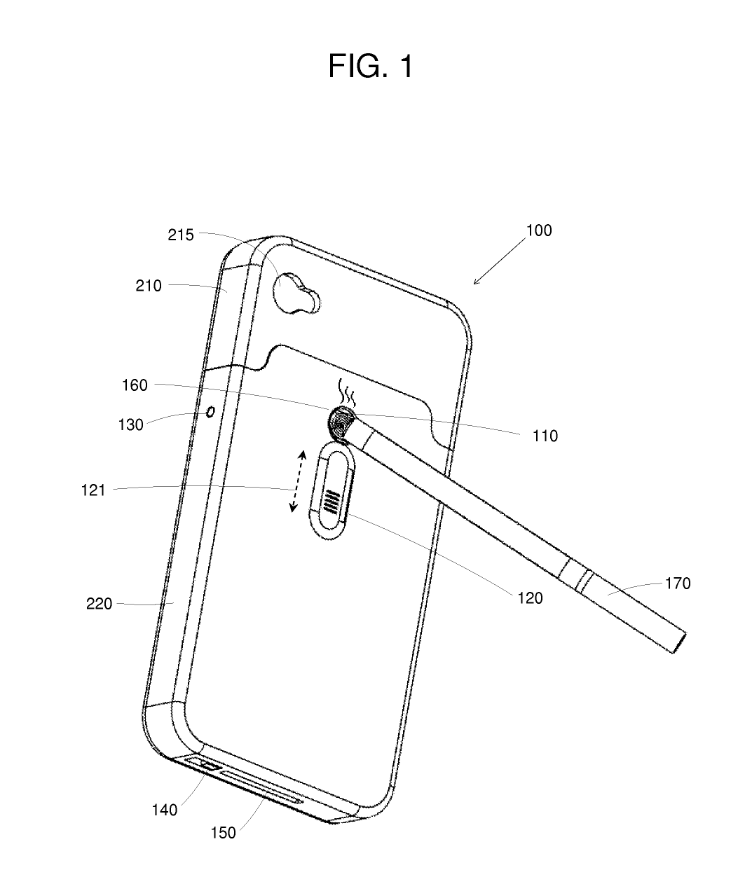

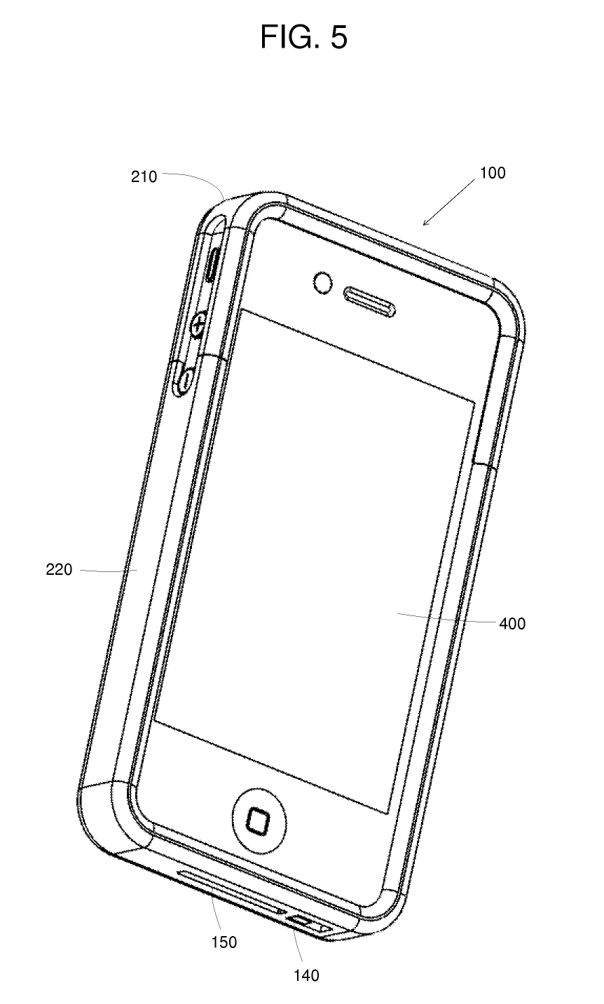

FIG. 1 is a perspective view of a mobile phone case 100 including a heating element 110 according to an exemplary embodiment. Case 100 is configured to house a mobile phone 400 (FIG. 5) having a charging port and a rechargeable battery. In addition to its technological features described below, case 100 is useful to protect the mobile phone from inadvertent user drops and scratches. According to an exemplary embodiment, case 100 is configured to fit any Apple iPhone® predating the Apple iPhone® 5. In this embodiment, mobile phone 400 is illustrated as an Apple iPhone 4®. In alternative embodiments, case 100 is configured to fit mobile phones including, but not limited to, a RiMM Blackberry®, a Samsung Galaxy®, an HTC Evo®, a Motorola RAZR®, a Palm Centro®, or an Apple iPhone® 5. Moreover, case 100 can be configured to house future mobile phones without changing the essence of the present invention.

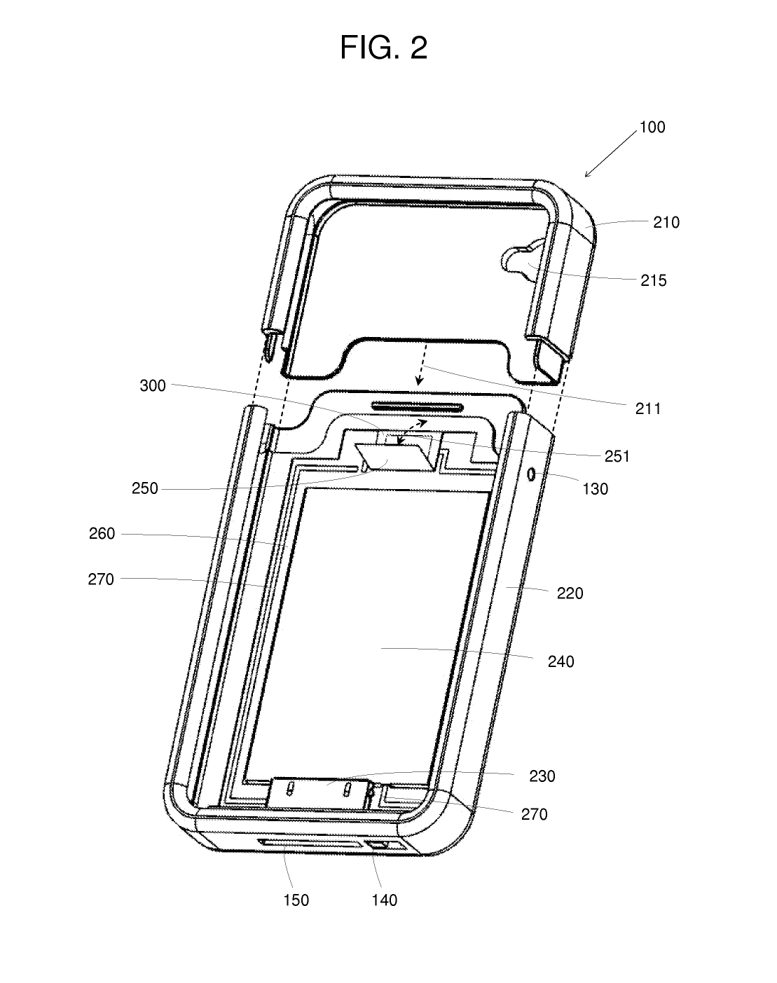

Still referring to FIG. 1, according to a further exemplary embodiment, a charging receptacle 150 is electrically connected to phone case 100 by means of a circuit board 260 (FIG. 2) and is configured to charge a rechargeable battery 240 (FIG. 2) enclosed internally within case 100. According to an exemplary embodiment, charging receptacle 150 is a thirty (30) pin dock connector found on Apple iPhones® predating the Apple iPhone® 5. According to an alternative embodiment, charging receptacle 150 is a Apple Lightning® connector used with the Apple iPhone® 5. According to other alternative embodiments, charging receptacle 150 is any type of charging receptacle used with smartphones, such as a Universal Serial Bus (USB), a mini-USB, and a micro-USB.

Still referring to FIG. 1, in order to operate heating element 110 for igniting materials such as a cigarette 170, a slide switch 120 moves back and forth in directions indicated by arrow 121. Movement of slide switch 120 to the open position shown in FIG. 1 exposes heating element 110 through an opening 160. This in turn also completes the heating circuit by using a slide-contact in slide switch 120, that physically interacts with circuit board 260 (FIG. 2) enclosed inside case 100. Slide switch 120 may automatically return to the closed position in a direction opposite of that in FIG. 1 by means of a spring-loaded mechanism so that the user must hold slide switch 120 down for reasons of safety. Simultaneously however, a momentary switch 130 must be depressed to operate heating element 110. Depressing momentary switch 130 in conjunction with moving slide switch 120 into the open position acts as a safety mechanism to prevent inadvertent activation of heating element 110. Thus, the user cannot activate heating element 110 by separately opening slide switch 120 or pressing momentary switch 130. According to an alternative embodiment, momentary switch 130 is a toggle switch, whereby the user can move the toggle switch to a closed position and only needs to move slide switch 120 into the open position to activate heating element 110. According to another alternative embodiment, switch 130 may be a rocker switch. According to a further alternative embodiment, switch 130 may be a push-button switch. And, according to another alternative embodiment, switch 130 may be a selector switch.

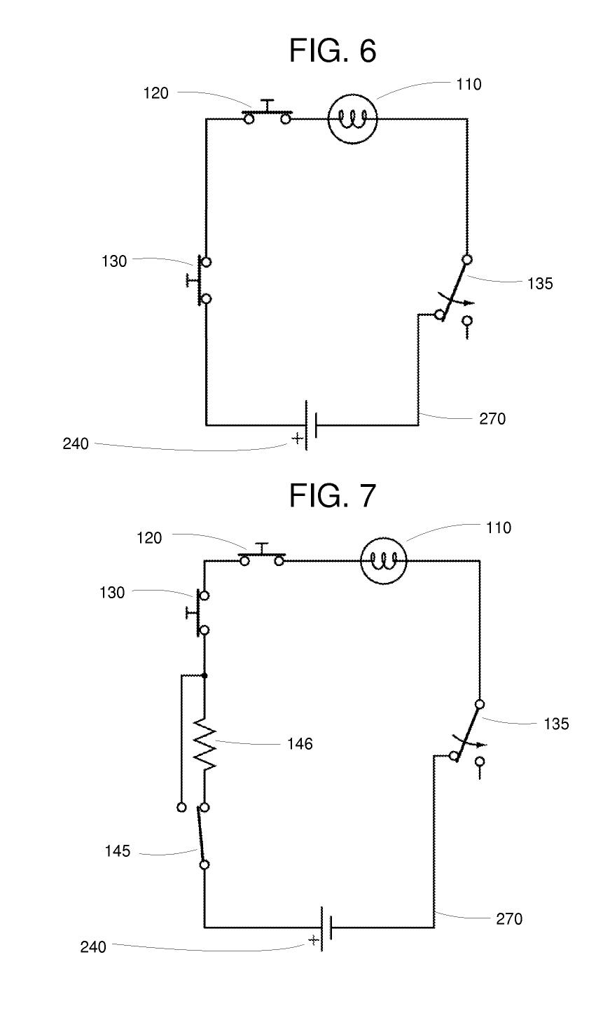

In an alternative embodiment illustrated in FIG. 6, case 100 may utilize a circuit containing a timer-activated switch 135 integrated with circuit board 260 (FIG. 2.) that prohibits heating element 110 from being activated for a length of time longer than a specified/pre-programmed amount of time despite momentary switch 130 being depressed and slide switch 120 being held in the open position. This is an additional safety mechanism that can be used to make the present invention even safer for its users.

Still referring to FIG. 1, a selector switch 140 controls charging of the mobile phone battery. According to an exemplary embodiment, selector switch 140 is a two-position switch configured to operate between an ON and an OFF position. When selector switch 140 is moved to the OFF position, rechargeable battery 240 (FIG. 2) enclosed within mobile phone case 100 does not provide electrical power through an adapter 230 (FIG. 2) to the mobile phone battery. When the selector switch 140 is in the ON position, rechargeable battery 240 (FIG. 2) enclosed within mobile phone case 100 provides electrical power through adapter 230 (FIG. 2) to recharge the mobile phone battery. According to an alternative embodiment, switch 140 may be a toggle switch. According to another alternative embodiment, switch 140 may be a push-button switch. According to an yet another alternative embodiment, switch 140 may be a rocker switch. Finally, this supplemental charging function may be used for auxiliary power in emergency situations when battery 240 of mobile phone 400 has depleted its normal charge, or it may be used to extend the original battery life by ideally doubling the normal charge capacity of mobile phone 400.

FIG. 1 also shows a cutout 215 in case 100 to allow for the use of an existing camera built into mobile phone 400. In an alternative embodiment, other cutouts may be placed in case 100 where needed to accommodate for other phone features, such as microphones, headphone jacks, speakers, light sensors, volume control buttons and other components applicable to modern-day smart phones.

FIG. 2 illustrates how case 100 fits together and how the internal components of case 100 interact with each other according to an exemplary embodiment. According to an exemplary embodiment, mobile phone case 100 is split into a first piece 210 and a second piece 220. First piece 210 and second piece 220 slide over the mobile phone and according to an exemplary embodiment, are snap connected to each other by pushing the pieces together in the direction of arrow 211. In alternative embodiments, the two pieces may be tight slip-fitted together. In an alternative embodiment, phone case 100 may be a single unit, not capable of being split into top and bottom pieces. In that embodiment, case 100 is pressed over the mobile phone. According to an exemplary embodiment, case 100 is plastic (or polymer) based. According to an alternative embodiment, case 100 may be metallic based.

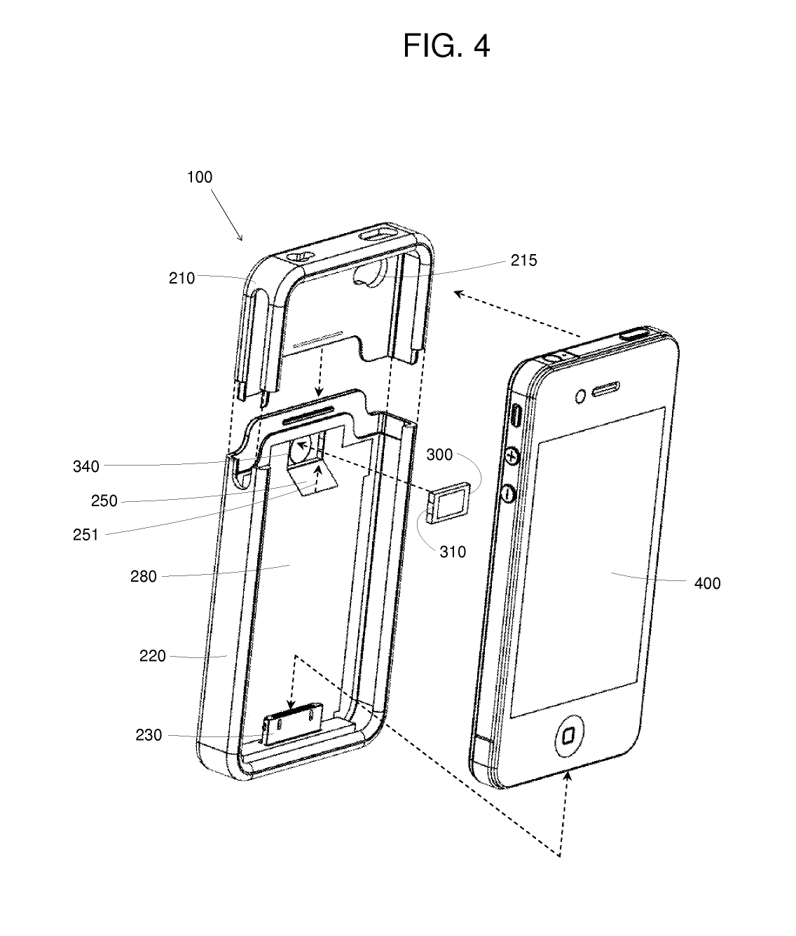

Still referring to FIG. 2, according to an exemplary embodiment, battery 240 is a lithium-polymer (LiPo) battery. According to a further exemplary embodiment, battery 240 is rechargeable. According to another exemplary embodiment, battery 240 is capable of supplying one (1) to five (5) Amps of electrical current to heating element 110 (FIG. 1) to preferably provide coil temperatures in the range of one thousand (1000) to two thousand (2000) degrees Fahrenheit required to combust cigarette 170 (FIG. 1), as well as other tobacco products, paper, leaves, tinder, or wick materials within 1 or 2 seconds. This method of lighting materials is more efficient than burning traditional lighter fuels, cleaner, and also eliminates the need for disposable products, in turn saving the user money in a long term situation as well as protecting the environment. Resistive heating elements are also not prone to the negative effects of a traditional lighter such as wind conditions, as well as wet conditions which could aid campers or backpackers more useful and reliable lighting tools in survival situations. This embodiment makes heating element 110 reusable by simply recharging battery 240 when depleted, using standard mobile phone chargers. In an alternative embodiment, battery 240 may be any lithium-based battery capable of being recharged and capable of supplying one (1) to five (5) Amps to heating element 110 (FIG. 1). Not shown in FIG. 2 for clarity but illustrated in FIG. 4, is a cover 280 (FIG. 4) used to enclose battery 240 and circuit board 260 within case 100. Cover 280 can be removed to allow for a replacement battery to be installed. In an alternative embodiment, battery 240 may be permanently enclosed within case 100, such that a user could not replace it. In yet another alternative embodiment, battery 240 may be permanently secured to circuit board 260, such that a user could not replace it.

Still referring to FIG. 2, adapter 230 is used to connect to the charging port on the mobile phone. According to an exemplary embodiment, adapter 230 is a thirty (30) pin connector configured to connect to Apple iPhones® predating the Apple iPhone® 5. According to an alternative embodiment, adapter 230 may be a Apple Lightning® connector used to connect with a Apple iPhone® 5. According to alternative embodiments, adapter 230 may be USB-based, such as a mini-USB or a micro-USB and configured to attach to other mobile smartphones. Other mobile smartphones include, but are not limited to, all variations of RiMM Blackberry®, Samsung Galaxy®, HTC Evo®, Motorola RAZR®, and Palm Centro®. As mentioned above, when selector switch 140 is moved into the ON position shown in FIG. 1, rechargeable battery 240 supplies electrical power through adapter 230 to provide a charge to the battery in the mobile phone 400. And, as also described above, battery 240 can be recharged using charging receptacle 150 while simultaneously charging the internal battery of mobile phone 400 as well. In an alternative embodiment, adapter 230 may be configured to charge battery 240 separate from the internal battery of mobile phone 400.

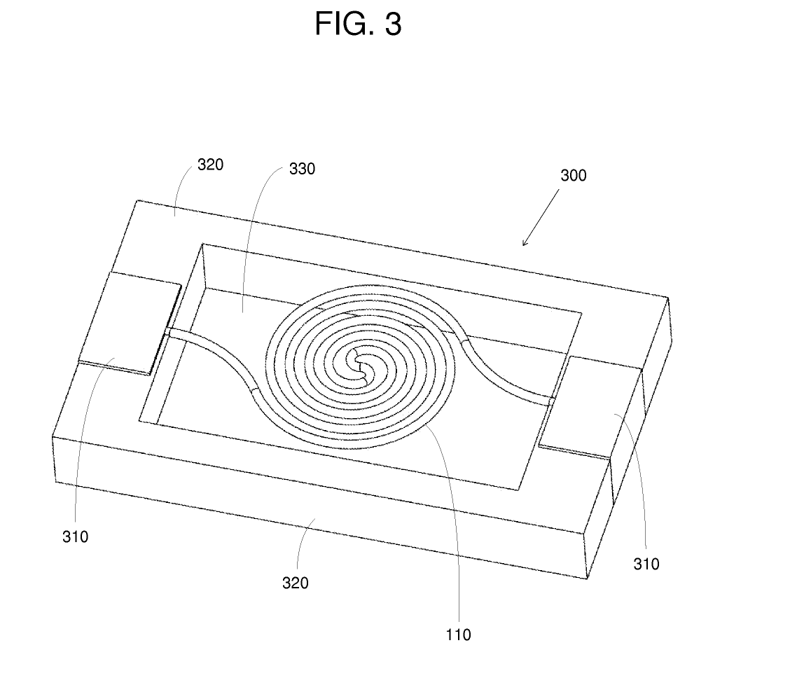

Referring to FIGS. 2 & 4, according to an exemplary embodiment, a heating element cartridge 300 is removably located in a receptacle 340, preferably by being press-fit into receptacle 340 and attached to circuit board 260 by direct contact. Heating element cartridge 300 is preferably accessed through a door 250 which opens and closes in direction of arrow 251. Door 250 may be provided to cover and secure heating element cartridge 300 (FIG. 3) in phone case 100. Door 250 is preferably accessible from the inside of phone case 100 where the back wall of mobile phone 400 sits against case 100. According to an exemplary embodiment, when door 250 is in the open position, cartridge 300 (FIG. 3) may be removed and replaced by seating it in receptacle 340 (FIG. 4) if cartridge 300 or heating element 110 were to fail by physical misuse or other means. In an exemplary embodiment, the inside face of door 250 includes a high-temperature plastic insulator, such as a polyimide, or ceramic insulator, such as alumina. According to an exemplary embodiment, door 250 is press-fit or snap connected to the case 100. According to an alternative embodiment, door 250 may be secured by means of a screw or other similar anchoring methods. According to another alternative embodiment, door 250 may be hinged to case 100 and can swing open and closed without being completely removed. According to an alternative embodiment, phone case 100 does not include door 250. In this embodiment, cartridge 300 (FIG. 3) is not removable and replaceable and its back wall may independently act as an insulator to mobile phone 400.

FIG. 3 is an exemplary embodiment depicting the removable and replaceable heating element cartridge 300. According to an exemplary embodiment, cartridge 300 holds heating element 110. According to a further exemplary embodiment, heating element 110 is a resistive heating element, where the generation of heat is directly proportional to the resistance in the conducting material that comprises heating element 110. According to exemplary embodiment, heating element 110 is secured to frame 320. Heating element 110 is preferably suspended in open air across a cavity 330 in frame 320. Cavity 330 separates heating element 110 from frame 320 to allow for proper heating of heating element 110 and to limit the transfer of heat to frame 320. In this embodiment, frame 320 is made of a high temperature plastic insulator capable of withstanding the temperatures required to ignite cigarette 170 (FIG. 1) and other similar materials. According to another exemplary embodiment, heating element 110 is nickel-chrome based. According to an alternative embodiment, heating element 110 may be a Kanthal® iron-chromium-aluminum alloy. As illustrated in FIGS. 1 & 3, heating element 100 is spiral shaped. In an alternative embodiment, heating element 110 may be serpentine shaped. In another alternative embodiment, heating element 110 may be shaped in other orientations not mentioned to provide the most efficient form of heat transfer.

Referring to FIG. 3, electrical contacts 310 allow electrical current from rechargeable battery 240 to flow through heating element 110 when the switches 120 & 130 are activated as described previously. According to an exemplary embodiment, electrical contacts 310 are aluminum or an aluminum alloy. In an alternative embodiment, electrical contacts 310 may be copper, gold, or a similar high electrical conductivity metal. According to an exemplary embodiment, the coil wire ends of heating element 110 are crimp-connected to terminal contact strips 310. In an alternative embodiment, the coil ends may be soldered to contacts 310. In an alternative embodiment, the coil ends may be brazed to contacts 310. When cartridge 300 is seated into receptacle 340, contacts 310 are electrically connected to heating element 110 with battery 240 via conductors 270 (FIG. 2) making heating element 110 operational. A high conductivity, low resistance metal is preferred for use as contacts 310. This allows the surface-to-surface contact between contacts 310 and circuit board 260 enclosed within case 100 to maintain electrical conductivity and minimize self-heating of contacts 310 through ohmic dissipation.

According to an alternative embodiment, electrical contacts 310 are soldered to circuit board 260 connected to battery 240. In this embodiment, cartridge 300 is fixed in case 100 and cannot be removed or replaced. Furthermore, according to other alternative embodiments, contacts 310 can be brazed or connected by any other means of electrical connection to circuit board 260 connected to battery 240. In these embodiments, cartridge 300 is fixed within case 100.

FIGS. 2 & 4 are an exploded view that illustrates assembly of case 100. In an exemplary embodiment, door 250 can swing open and closed so that cartridge 300 can be seated into receptacle 340 and allow electrical contacts 310 to make contact with conductors 270 (FIG. 2) on circuit board 260. Once this piece is secured, first piece 210 is removed so that a mobile phone can be inserted into second piece 220 and connected to adapter 230. First piece 210 is then replaced and the heating element 110 is operated by activating both switches simultaneously.

FIG. 5 is an assembled front view showing case 100 housing mobile phone 400 and ready for operation.

FIG. 6 is a schematic illustration of an exemplary circuit used to power heating element 110. In this embodiment, it is noted that the components in FIG. 6 depict the main switches, conductors, battery, and other important electrical components described thus far, relating to the heating circuit, but are not limited to, integrated circuits, microchips, capacitors, resistors, rectifiers, transistors, thyristors, semiconductors and other more complex circuitry required for the charging circuit. In this exemplary embodiment, when slide switch 120 and momentary switch 130 are in a closed-circuit position, as well as timer-switch 135, the circuit is completed. Rechargeable battery 240 will then allow power to heating element 110 via conductors 270 and heating can occur as outlined in previous sections.

Referring to FIG. 7, in an alternative embodiment, the circuit shown functions the same way as the circuit shown in FIG. 6, but with the inclusion of a heating mode switch 145 (FIG. 7). In this alterative embodiment switch 145 can add or remove a resistor 146 (FIG. 7) into the heating circuit to provide low and high heating modes. This would allow the option for battery life to be saved when lighting light-duty materials such as cigarettes, and would also be able to provide sufficient thermal power when lighting heavy-duty materials such as cigars, and wax candles. This alterative embodiment may provide an external switch on case 100 similar to the two-position switch 140 described in FIG. 1.

In operation, the user picks up cell phone case 100 and separates first piece 210 and second piece 220. The user then slides mobile phone 400 into second piece 220. Once mobile phone 400 is properly seated and secured over adapter 230, first piece 210 is replaced and slides over mobile phone 400. In order for the user to ignite cigarette 170, preferably a thumb can be used to move slide switch 120 in a direction shown by arrow 121 to expose heating element 110, while also using another finger to simultaneously depress momentary switch 130. Once this sequence is complete, heating element 110 will heat to a usable temperature and glow to indicate successful operation. The user may then hold the end of cigarette 170 up to heating element 110 through opening 160 will simultaneously inhaling cigarette 170. The result is a lit cigarette 170 with the use of no combustible fuels or disposable products.

Although the present invention has been described with reference to example embodiments, those skilled in the art will recognize that changes may be made in form and detail without departing from the spirit and scope of the invention. The invention is not limited to a particular embodiment, but extends to various modifications, combinations, and permutations that nevertheless fall within the scope and spirit of the appended claims.

I claim:

1. A case for a mobile phone comprising:
a housing for holding a mobile phone;
a removable rechargeable battery attached to the housing;
a charging receptacle electrically connected to the rechargeable battery and configured to charge the rechargeable battery;
an adapter electrically connected to the rechargeable battery, wherein the adapter is configured to electrically connect to the mobile phone; and
a heating element electrically connected to the rechargeable battery.

2. The case of claim 1, wherein the housing includes a switch configured to operate between an on and an off position.

3. The case of claim 2, wherein when the switch is in the on position, the rechargeable battery provides electrical current through the adapter to the mobile phone.

4. The case of claim 3, wherein the heating element is a resistive heating element.

5. The case of claim 4, wherein the resistive heating element is coil shaped.

6. The case of claim 5, wherein the resistive heating element is electrically connected to a momentary switch and a slide switch.

7. The case of claim 6, wherein the slide switch is movable between a closed and an open position.

8. The case of claim 7, wherein when in the open position, the slide switch is configured to allow the heating element to be exposed.

9. The case of claim 6, wherein the momentary switch is attached to the side of the housing.

10. The case of claim 6, wherein the heating element is configured to operate when the momentary switch is depressed and the slide switch is put in the open position.

11. The case of claim 10, wherein the heating element is electrically connected to a timer switch attached to the housing and configured to allow the heating element to operate for a specified amount of time.

12. A case comprising:
a housing for holding a mobile phone;
a removable rechargeable battery attached to the housing;
a charging receptacle electrically connected to the rechargeable battery and configured to charge the rechargeable battery;
an adapter electrically connected to the rechargeable battery, wherein the adapter is configured to electrically connect to the mobile phone; and
a cartridge configured to hold a heating element, wherein the cartridge is movably attached to the case.

13. The case of claim 12, wherein the heating element is electrically connected to the rechargeable battery when the cartridge is attached to the case.

14. The case of claim 13, wherein the heating element is a resistive heating element.

15. The case of claim 14, wherein the heating element is coil shaped.

16. The case of claim 14, wherein the heating element is electrically connected to a momentary switch and a slide switch.

17. The case of claim 16, wherein the slide switch is movable between a closed and an open position.

18. The case of claim 17, wherein when in the open position, the slide switch is configured to allow the heating element to be exposed.

19. The case of claim 16, wherein the heating element is configured to operate when the momentary switch is depressed and the slide switch is put in the open position.

20. The case of claim 19, wherein the heating element is electrically connected to a timer switch configured to allow the heating element to operate for a specified amount of time.
